(19) United States
(12) Patent Application Publication
(10) Pub. No.: US 2012/0280425 A1
(43) Pub. Date: Nov. 8, 2012

(54) MOLD FOR MEASURING FLOW CHARACTERISTICS, METHOD FOR MEASURING FLOW CHARACTERISTICS, RESIN COMPOSITION FOR ENCAPSULATING SEMICONDUCTOR, AND METHOD FOR MANUFACTURING SEMICONDUCTOR APPARATUS

(75) Inventor: Atsunori Nishikawa, Shinagawa-ku (JP)

(73) Assignee: Sumitomo Bakelite Co., Ltd., Tokyo (JP)

(21) Appl. No.: 13/511,501

(22) PCT Filed: Nov. 17, 2010
(86) PCT No.: PCT/JP2010/006733

§ 371 Date: May 23, 2012

(30) Foreign Application Priority Data
Nov. 24, 2009 (JP) 2009-265872

(51) Int. Cl. G01N 11/00; C09D 163/00; H01L 21/56

(52) U.S. Cl. 264/272.17; 73/54.01; 523/466

(57) ABSTRACT

According to the invention, a mold for measuring flow characteristics which is used to measure the flow characteristics of a resin composition, which is a measurement subject, by injecting the resin composition into a flow path provided in the mold, in which the minimum distance from the cross-sectional center of gravity to the outline in the cross-sectional shape of the flow path is equal to or more than 0.02 mm and equal to or less than 0.4 mm, and a method for measuring flow characteristics in which a resin composition, which is a measurement subject, is injected into the flow path of the mold for measuring flow characteristics, and made to flow in a single direction, and the flow distance from the start point to the end point of the flow of the resin composition is obtained as the flow length are provided.

### TECHNICAL FIELD

The present invention relates to a mold for measuring flow characteristics, a method for measuring flow characteristics, a resin composition for encapsulating a semiconductor, and a method for manufacturing a semiconductor apparatus, and particularly to a mold for measuring flow characteristics and a method for measuring flow characteristics which are appropriate for evaluation of narrow path filling properties during encapsulating molding of a semiconductor element using a resin composition for encapsulating a semiconductor, a resin composition for encapsulating a semiconductor which is selected by the method for measuring flow characteristics, and a method for manufacturing a semiconductor apparatus in which the resin composition for encapsulating a semiconductor is used.

### BACKGROUND ART

As a method for encapsulating a semiconductor element, such as an IC and an LSI, transfer molding of a resin composition costs little, is appropriate for mass production, and thus has long been employed. The characteristics also have been improved through improvement of an epoxy resin or a phenol resin which is a curing agent in terms of reliability. However, since further integration of semiconductors has progressed year by year in accordance with the recent market trend of electronic devices being smaller and lighter and having better performances, and surface mounting of semiconductor apparatuses has been promoted, there has been an increasing demand for a resin composition for encapsulating a semiconductor having narrow path filling properties. As a result, a method for evaluating flow characteristics which can consistently reflect the narrow path filling properties is becoming extremely important.

Hitherto, flow characteristics measurement, in which a mold for measuring spiral flow, which is defined in ANSI/ASTM D 3123-72, is used, a resin composition, which is a measurement subject, is injected into a spiral-shaped flow path, and the flow length of the resin composition is measured, has been frequently used as a method for evaluating the flow characteristics of a resin composition for encapsulating a semiconductor (for example, refer to Patent Document 1). However, the cross-sectional shape of the spiral-shaped flow path in the mold for measuring spiral flow, which is defined in ANSI/ASTM D 3123-72, is a semicircular shape having a radius of R1.6 mm (R0.63 inches), which is large, and the above evaluation method could consistently reflect the filling properties of a resin composition for encapsulating a semiconductor in a semiconductor apparatus sufficiently for semiconductor apparatuses of previous and present days; however, for small-sized semiconductor apparatuses which are in conformity with the recent trend of being thin, consistency between spiral flow measurement results and the narrow path filling properties of actual semiconductor apparatuses has not been sufficient. In addition, the flow length of the spiral-shaped flow path defined for the mold for measuring spiral flow, which is defined in ANSI/ASTM D 3123-72, is approximately 102 inches (approximately 260 cm), and it was not possible to evaluate the flow characteristics of a resin composition having high fluidity for which the flow length exceeds the above.

Due to the above circumstances, in the past, narrow path filling properties were evaluated using actual semiconductor elements. For example, a method in which a flip chip is surface-mounted on a MAP substrate, a resin composition for encapsulating a semiconductor is actually flowed on the substrate, and the narrow path filling properties are evaluated using an ultrasonic image measurement apparatus or the like is the only method. An IC chip was extremely expensive, an extremely large number of man-hours, such as in efforts for surface mounting were required for the evaluation, and the efficiency was poor. In addition, for example, in flow characteristics evaluation, in which the mold for measuring spiral flow is used, of a resin composition for encapsulating a semiconductor which is appropriate for encapsulating molding of multilaterally laminated semiconductor elements, it has not been possible to quantitatively evaluate the flow characteristics of a resin composition having high fluidity for which the flow length exceeds 102 inches (260 cm).

### RELATED DOCUMENT

### Patent Document

[Patent Document 1] Japanese Laid-open Patent Publication No. 2008-291155

### DISCLOSURE OF THE INVENTION

The invention has been made in consideration of the above circumstances, and an object of the invention is to provide a method for conveniently evaluating narrow path filling properties during encapsulating molding of a semiconductor element using a resin composition for encapsulating a semiconductor at low cost without using an expensive IC chip. In addition, another object is to provide a method in which the flow characteristics of a resin composition having an extremely high fluidity can be quantitatively evaluated.

According to the invention, a mold for measuring flow characteristics which is used to measure the flow characteristics of a resin composition, which is a measurement subject, by injecting the resin composition into a flow path provided in the mold, in which the minimum distance from the cross-sectional center of gravity to the outline in the cross-sectional shape of the flow path is equal to or more than 0.02 mm and equal to or less than 0.4 mm is provided.

According to an embodiment of the invention, in the mold for measuring flow characteristics, the flow path is a spiral-shaped flow path.

According to an embodiment of the invention, in the mold for measuring flow characteristics, the cross-sectional shape of the flow path is a rectangular form, a trapezoidal form, or a semicylindrical form.

According to an embodiment of the invention, in the mold for measuring flow characteristics, the maximum width (w) and the maximum height (h) in the cross-sectional shape of the flow path have a relationship of w≦h.

According to an embodiment of the invention, in the mold for measuring flow characteristics, the maximum height of the cross-sectional shape of the flow path is equal to or more than 0.05 mm and equal to or less than 0.8 mm.

According to an embodiment of the invention, in the mold for measuring flow characteristics, the maximum width of the cross-sectional shape of the flow path is equal to or more than 0.5 mm and equal to or less than 10 mm.

According to the invention, a method for measuring flow characteristics including a process in which a resin composition, which is a measurement subject, is injected into the flow path of the mold for measuring flow characteristics, and made to flow in a single direction, and a process in which a flow distance from a start point to an end point of the flow of the resin composition is obtained as a flow length is provided.

According to an embodiment of the invention, in the method for measuring flow characteristics, the process in which the flow distance is obtained as the flow length is carried out using a low-pressure transfer molder under conditions of a mold temperature of 140° C. to 190° C., an injection pressure of 6.9 MPa, and a pressurization time of 60 seconds to 180 seconds.

According to the invention, a method for inspecting a resin composition including: evaluating the flow characteristics of the resin composition by the method for measuring flow characteristics, in which the resin composition is a resin composition for encapsulating a semiconductor, and a process in which the flow length of the resin composition for encapsulating a semiconductor is measured for a product inspection of the resin composition for encapsulating a semiconductor, the value is compared with a previously specified product standard, and whether a pass or a fail is determined is provided.

According to the invention, a resin composition for encapsulating a semiconductor which includes (A) an epoxy resin, (B) a phenol resin-based curing agent, (C) an inorganic filler, and (D) a curing accelerator, in which the flow length measured by injecting the resin composition for encapsulating a semiconductor into the flow path in the mold for measuring flow characteristics having a spiral-shaped flow path, the cross-sectional shape of which is substantially a 5 mm-wide and 0.2 mm-high rectangular form, using a low-pressure transfer molder according to the method for measuring flow characteristics under conditions of a mold temperature of 175° C., an injection pressure of 6.9 MPa, and a pressurization time of 120 seconds is equal to or more than 50 cm, is provided.

According to an embodiment of the invention, when L₁ indicates the flow length measured by injecting the resin composition for encapsulating a semiconductor into the flow path in the mold for measuring flow characteristics having a spiral-shaped flow path, the cross-sectional shape of which is substantially a 5 mm-wide and 0.2 mm-high rectangular form, using a low-pressure transfer molder according to the method for measuring flow characteristics under conditions of a mold temperature of 175° C., an injection pressure of 6.9 MPa, and a pressurization time of 120 seconds, and L₂ indicates the flow length measured by injecting the resin composition for encapsulating a semiconductor into a flow path in a mold for measuring spiral-shaped flow, which is defined in ANSI/ASTM D 3123-72, having a spiral-shaped flow path, and the cross-sectional shape of which is a semicircular shape having a radius of R1.6 mm, using a low-pressure transfer molder according to the method for measuring flow characteristics under conditions of a mold temperature of 175° C., an injection pressure of 6.9 MPa, and a pressurization time of 120 seconds,

the following formula:

0.25L₂≦L₁

is satisfied.

According to an embodiment of the invention, the resin composition for encapsulating a semiconductor has a flow length, which is measured by injecting the resin composition for encapsulating a semiconductor into the flow path in the mold for measuring flow characteristics having a spiral-shaped flow path, the cross-sectional shape of which is substantially a 5 mm-wide and 0.2 mm-high rectangular form, using a low-pressure transfer molder according to the method for measuring flow characteristics under conditions of a mold temperature of 175° C., an injection pressure of 6.9 MPa, and a pressurization time of 120 seconds, of equal to or more than 60 cm.

According to an embodiment of the invention, the resin composition for encapsulating a semiconductor has a flow length, which is measured by injecting the resin composition for encapsulating a semiconductor into the flow path in the mold for measuring flow characteristics having a spiral-shaped flow path, the cross-sectional shape of which has substantially a 5 mm-wide and 0.2 mm-high rectangular form, using a low-pressure transfer molder according to the method for measuring flow characteristics under conditions of a mold temperature of 175° C., an injection pressure of 6.9 MPa, and a pressurization time of 120 seconds, of equal to or more than 80 cm.

According to the invention, a method for manufacturing a semiconductor apparatus including: encapsulating and molding one or more semiconductor elements stacked or mounted in parallel on a lead frame or a circuit substrate having die pad portion, using the resin composition for encapsulating a semiconductor, and the semiconductor apparatus has a narrow path having the minimum height of equal to or more than 0.01 mm and equal to or less than 0.1 mm is provided.

According to the invention, since it is possible to stably obtain a resin composition for encapsulating a semiconductor which is excellent in terms of narrow path filling properties and a resin composition for encapsulating a semiconductor having extremely high fluidity, the invention can be preferably used for selection of a resin composition for encapsulating a semiconductor which is useful for a semiconductor apparatus having a narrow path, a semiconductor apparatus having multilaterally laminated semiconductor elements, and the like, for use in quality control, and the like.

According to the invention, it is possible to conveniently evaluate narrow path filling properties during encapsulating molding of a semiconductor element using a resin composition for encapsulating a semiconductor at low cost, and to quantitatively evaluate the flow characteristics of a resin composition having extremely high fluidity. In addition, it is possible to stably obtain a resin composition for encapsulating a semiconductor which is excellent in terms of the narrow path filling properties and a semiconductor apparatus having no poor filling and the like by controlling the quality of the resin composition for encapsulating a semiconductor by the present method.

### BRIEF DESCRIPTION OF THE DRAWINGS

FIG. 1 is a view showing the bottom mold cavity of an example of a mold for measuring flow characteristics according to the invention.

FIG. 2 is a view showing a cross-sectional structure of an example a semiconductor apparatus of the invention.

### DESCRIPTION OF EMBODIMENTS

The mold for measuring flow characteristics of the invention is a mold for measuring flow characteristics which is used to measure the flow characteristics of a resin composition, which is a measurement subject, by injecting the resin composition into a flow path provided in the mold, in which the minimum distance from the cross-sectional center of gravity to the outline in the cross-sectional shape of the flow path is equal to or more than 0.02 mm and equal to or less than 0.4 mm. In addition, in the method for measuring flow characteristics of the invention, a resin composition, which is a measurement subject, is injected into the flow path of the mold for measuring flow characteristics, and made to flow in a single direction, and the flow distance from the start point to the end point of the flow of the resin composition is obtained as the flow length. Thereby, it becomes possible to conveniently evaluate narrow path filling properties during encapsulating molding of a semiconductor element using a resin composition for encapsulating a semiconductor at low cost, and to quantitatively evaluate the flow characteristics of a resin composition having extremely high fluidity.

In addition, the resin composition for encapsulating a semiconductor of the invention is a resin composition for encapsulating a semiconductor which includes (A) an epoxy resin, (B) a phenol resin-based curing agent, (C) an inorganic filler, and (D) a curing accelerator, in which the flow length measured by injecting the resin composition for encapsulating a semiconductor into the flow path in the mold for measuring flow characteristics having a spiral-shaped flow path, the cross-sectional shape of which is substantially a 5 mm-wide and 0.2 mm-high rectangular form, using a low-pressure transfer molder according to the method for measuring flow characteristics under conditions of a mold temperature of 175° C., an injection pressure of 6.9 MPa, and a pressurization time of 120 seconds is equal to or more than 50 cm. Thereby, it is possible to stably obtain a resin composition for encapsulating a semiconductor which is excellent in terms of the narrow path filling properties, or a resin composition for encapsulating a semiconductor having extremely high fluidity. Furthermore, in the method for manufacturing a semiconductor apparatus of the invention, one or more semiconductor elements stacked or mounted in parallel on a lead frame or circuit substrate having a die pad portion are encapsulating-molded using the resin composition for encapsulating a semiconductor. Thereby, it is possible to stably obtain a semiconductor apparatus having no poor filling and the like even when the semiconductor apparatus has a narrow path of equal to or more than 0.01 mm and equal to or less than 0.1 mm. Hereinafter, the invention will be described in detail.

Firstly, the mold for measuring flow characteristics and the method for measuring flow characteristics of the invention will be described. The mold for measuring flow characteristics of the invention is a mold for measuring flow characteristics which is used to measure the flow characteristics of a resin composition, which is a measurement subject, by injecting the resin composition into a flow path provided in the mold, in which the minimum distance from the cross-sectional center of gravity to the outline in the cross-sectional shape of the flow path can be equal to or more than 0.02 mm and equal to or less than 0.4 mm. Thereby, it becomes possible to conveniently evaluate narrow path filling properties during encapsulating molding of a semiconductor element using a resin composition for encapsulating a semiconductor at low cost, and to quantitatively evaluate the flow characteristics of a resin composition having extremely high fluidity.

In the mold for measuring flow characteristic of the invention, the minimum distance from the cross-sectional center of gravity to the outline in the cross-sectional shape of the flow path is preferably equal to or more than 0.02 mm and equal to or less than 0.4 mm, and more preferably equal to or more than 0.04 mm and equal to or less than 0.3 mm in a case in which consistency with narrow path filling properties during MAP molding in which a semiconductor apparatus having a flip chip surface-molded on a MAP substrate, or the like is encapsulating-molded using a resin composition for encapsulating a semiconductor is taken into account.

In a mold for measuring spiral flow of the related art, which is defined in ANSI/ASTM D 3123-72, since the cross-sectional shape of the flow path is a semicircular shape having R1.6 mm (R0.63 inches), and the minimum distance from the cross-sectional center of gravity to the outline is approximately 0.7 mm, which is large, the quantity of heat received from the mold surface is small compared to the quantity of heat received in an actual semiconductor apparatus having a narrow path, and curing of a resin becomes relatively slow, and therefore, consequently, the filling properties of an actual semiconductor apparatus is not consistently reflected. In contrast to the above, in the mold for measuring flow characteristics of the invention, when the minimum distance from the cross-sectional center of gravity to the outline in the cross-sectional shape of the flow path is set to the above range, consistency with the filling properties in an actual semiconductor apparatus having a narrow path also can be improved.

The flow path in the mold for measuring flow characteristics of the invention is not particularly limited, but a spiral-shaped flow path is preferred since the size of the mold can be made compact without hindering the flow of a resin.

The cross-sectional shape of the flow path in the mold for measuring flow characteristics of the invention is not particularly limited, and may be any of a rectangular form, a trapezoidal form, a semicylindrical form, a semi-circular form, a triangular form, and a circular form, but is preferably a rectangular form, a trapezoidal form, or a semicylindrical form which is similar to the shape of a flow path in an actual semiconductor apparatus from the viewpoint of the consistency with the filling properties in an actual semiconductor apparatus having a narrow path. In other words, the maximum width (w) and the maximum height (h) preferably have a relationship of w≦h. The above shape is also preferred since the flow amount of a resin composition, which is a measurement subject, can be relatively large even in a case in which the maximum height is small, and therefore measurement variation can be reduced. Further, in a case in which the cross-sectional shape of the flow path is a rectangular form, in order to become easy to eject the resin composition from the mold, the side surface may be tapered, or the edge portions may be rounded.

With regard to the maximum height of the cross-sectional shape of the flow path in the mold for measuring flow characteristics of the invention, consistency with the filling properties in an actual semiconductor apparatus can be improved by appropriately selecting the maximum height in accordance with the shape of an actual semiconductor apparatus having the narrow path, but the maximum height is preferably equal to or more than 0.05 mm and equal to or less than 0.8 mm. Particularly, in a case in which consistency with narrow path filling properties during MAP molding in which a semiconductor apparatus having a flip chip surface-molded on a MAP substrate, or the like is encapsulating-molded using a resin composition for encapsulating a semiconductor is taken into account, the maximum height is preferably equal to or more than 0.08 mm and equal to or less than 0.6 mm.

With regard to the maximum width of the cross-sectional shape of the flow path in the mold for measuring flow characteristics of the invention, consistency with the filling properties in an actual semiconductor apparatus can be improved by appropriately selecting the maximum width in accordance with the shape of an actual semiconductor apparatus having the narrow path, but the maximum width is preferably equal to or more than 0.5 mm and equal to or less than 10 mm. Particularly, in a case in which consistency with narrow path filling properties during MAP molding in which a semiconductor apparatus having a flip chip surface-molded on a MAP substrate, or the like is encapsulating-molded using a resin composition for encapsulating a semiconductor is taken into account, the maximum height is preferably equal to or more than 0.8 mm and equal to or less than 8 mm.

The length of the flow path in the mold for measuring flow characteristics of the invention can be appropriately set depending on the flow characteristics of a resin composition, which is a measurement subject, and is not particularly limited, but is preferably equal to or more than 70 cm and equal to or less than 160 cm, and more preferably equal to or more than 80 cm and equal to or less than 150 cm. Particularly, in a case in which consistency with narrow path filling properties during MAP molding in which a semiconductor apparatus having a flip chip surface-molded on a MAP substrate, or the like is encapsulating-molded using a resin composition for encapsulating a semiconductor is taken into account, the length is preferably equal to or more than 90 cm and equal to or less than 140 cm. In addition, when the length of the flow path in the mold for measuring flow characteristics is equal to or more than 80 cm, the flow characteristics can be quantitatively evaluated even for a resin composition having high fluidity for which the flow length exceeds 102 inches (260 cm) in evaluation of flow characteristics in which the mold for measuring spiral flow of the related art is used.

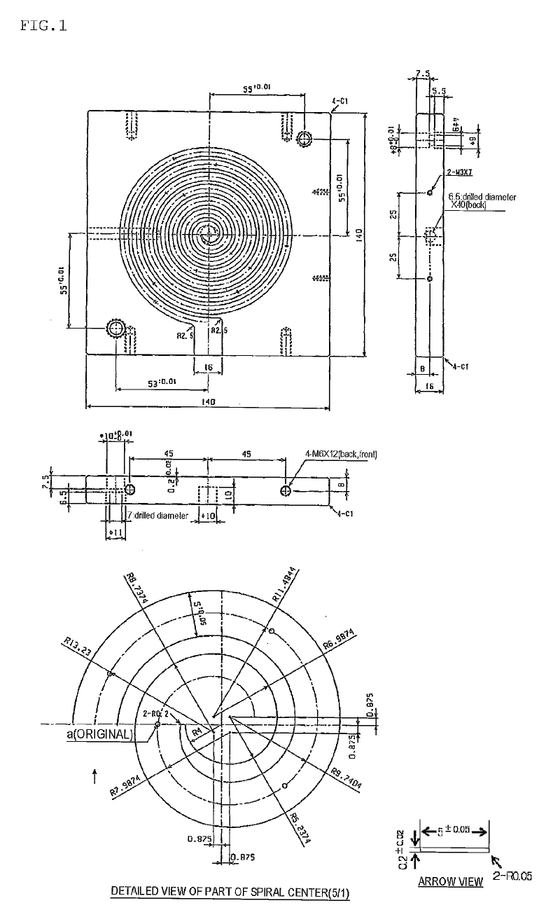

FIG. 1 is a view showing a bottom mold cavity of an example of the mold for measuring flow characteristics of the invention. The mold for measuring flow characteristics as shown in FIG. 1 has a flow path having a cross-sectional shape of a rectangular form as shown by the “arrow view” in FIG. 1. As shown in the same drawing, the cross-sectional shape of the flow path is a 5 mm-wide and 0.2 mm-high rectangular form, and the minimum distance from the cross-sectional center of gravity to the outline is 0.1 mm. In addition, the flow path has a spiral shape having a flow length of 113 cm.

In the method for measuring flow characteristics of the invention, a resin composition, which is a measurement subject, is injected into the flow path of the mold for measuring flow characteristics, and made to flow in a single direction, and the flow distance from the start point to the end point of the flow of the resin composition is obtained as the flow length, whereby it is possible to conveniently evaluate narrow path filling properties during encapsulating molding of a semiconductor element using a resin composition for encapsulating a semiconductor at low cost. The method for injecting the resin composition, which is a measurement subject, into the flow path of the mold for measuring flow characteristics and conditions thereof are not particularly limited, and, the resin composition can be injected, for example, using a low-pressure transfer molder under conditions of a mold temperature of 140° C. to 190° C., an injection pressure of 6.9 MPa, and a pressurization time of 60 seconds to 180 seconds.

In the invention, pass or fail can be determined by measuring the flow length of the resin composition for encapsulating a semiconductor as a product inspection thereof according to the method for measuring flow characteristics of the invention in which the mold for measuring flow characteristics of the invention is used and comparing the value with a previously specified product standard. A resin composition for encapsulating a semiconductor which is excellent in terms of the narrow path filling properties, or a resin composition for encapsulating a semiconductor having extremely high fluidity can be stably obtained by managing the flow characteristics of the resin composition for encapsulating a semiconductor within a predetermined range in the above manner.

Next, the resin composition for encapsulating a semiconductor of the invention will be described. The resin composition for encapsulating a semiconductor of the invention is a resin composition for encapsulating a semiconductor which includes (A) an epoxy resin, (B) a phenol resin-based curing agent, (C) an inorganic filler, and (D) a curing accelerator, in which the flow length, which is the flow distance from the start point to the end point of the flow, measured by injecting the resin composition for encapsulating a semiconductor according to the method for measuring flow characteristics of the invention into the flow path in the mold for measuring flow characteristics having a spiral-shaped flow path, the cross-sectional shape of which is substantially a 5 mm-wide and 0.2 mm-high rectangular form, using a low-pressure transfer molder according to the method for measuring flow characteristics of the invention under conditions of a mold temperature of 175° C., an injection pressure of 6.9 MPa, and a pressurization time of 120 seconds is preferably equal to or more than 50 cm, more preferably equal to or more than 60 cm, and still more preferably equal to or more than 80 cm. Thereby, a resin composition for encapsulating a semiconductor which is appropriate for a semiconductor apparatus having a narrow path, or a semiconductor apparatus having multilaterally laminated semiconductor elements can be obtained.

In addition, in a case in which narrow path filling properties during MAP molding in which a semiconductor apparatus having a flip chip surface-molded on a MAP substrate, or the like is encapsulating-molded using a resin composition for encapsulating a semiconductor is taken into account, when L₁ indicates the flow length measured by injecting the resin composition for encapsulating a semiconductor into the flow path in the mold for measuring flow characteristics of the invention having a spiral-shaped flow path, the cross-sectional shape of which is substantially a 5 mm-wide and 0.2 mm-high rectangular form, using a low-pressure transfer molder according to the method for measuring flow characteristics of the invention under conditions of a mold temperature of 175° C., an injection pressure of 6.9 MPa, and a pressurization time of 120 seconds, and L₂ indicates the flow length measured by injecting the resin composition for encapsulating a semiconductor into the flow path in the mold for measuring spiral flow, which is defined in ANSI/ASTM D 3123-72, having a spiral-shaped flow path, and the cross-sectional shape of which is a semicircular shape having a radius of R1.6 mm, using a low-pressure transfer molder under conditions of a mold temperature of 175° C., an injection pressure of 6.9 MPa, and a pressurization time of 120 seconds,

the following formula:

0.25L₂≦L₁

is preferably satisfied.

Compared with a case in which as many semiconductor elements as in one package are installed and encapsulated with a resin in the mold cavity, in MAP molding in which as many semiconductor elements as in a plurality of packages are installed and encapsulated with a resin collectively in a mold cavity, it is necessary to flow the encapsulating resin a long distance in a narrow path having a height of approximately 0.2 mm. It becomes possible to flow the encapsulating resin over a long distance in a narrow path having a height of approximately 0.2 mm by using a resin composition having a flow length relationship between L₁ and L₂ in the above range.

For the encapsulating resin of the related art for which it was imagined that as many semiconductor elements as in one package are installed and encapsulated with a resin in the mold cavity, since curing properties were considered to be important from the viewpoint of productivity, and the value of L₁ fell below 0.25L₂. In this case, even if the flow length in a spiral flow mold, which is a method for measuring flow characteristics of the related art, exceeded 200 cm, the flow length in a mold for evaluating flow characteristics of the invention fell below 50 cm, there was insufficient fluidity during MAP molding, and poor filling occurred. Particularly, in a case in which a semiconductor apparatus having a flip chip surface-molded on a MAP substrate, or the like is encapsulating-molded using a resin composition for encapsulating a semiconductor, there is a case in which the gap between the flip chip and the substrate becomes approximately 0.01 mm to 0.1 mm, and, with respect to this, an encapsulating resin having a flow length in the mold for evaluating flow characteristics of the invention of equal to or more than 60 cm is preferably used.

In the invention, the flow length of the resin composition for encapsulating a semiconductor, which is measured by the above method, can be set to equal to or more than the above lower limit by appropriately selecting the kinds or blending ratios of (A) the epoxy resin, (B) the phenol resin-based curing agent, (C) the inorganic filler, and (D) the curing accelerator, and adjusting the melt viscosity and curing properties of the resin composition. In addition, since the flow length of the resin composition is influenced by blending of particles having a large particle size, the flow length can be adjusted by controlling the particle size distribution of (C) the inorganic filler. Hereinafter, the respective components of the resin composition for encapsulating a semiconductor will be described in detail.

The resin composition for encapsulating semiconductors of the invention includes the epoxy resin (A). The epoxy resin (A) that is used in the resin composition for encapsulating semiconductors of the invention comprehensively includes monomers, oligomers, and polymers which have two or more epoxy groups in one molecule, and the molecular weight and the molecular structure are not particularly limited. Examples thereof include crystalline epoxy resins, such as biphenyl-type epoxy resins, bisphenol F-type epoxy resins, bisphenol A-type epoxy resins, and stilbene-type epoxy resins; novolac-type epoxy resins, such as phenol novolac-type epoxy resins, cresol novolac-type epoxy resins, and naphthol novolac-type epoxy resins; multifunctional epoxy resins, such as triphenolmethane-type epoxy resins, and alkyl-modified triphenolmethane-type epoxy resins; aralkyl-type epoxy resins, such as phenol aralkyl-type epoxy resins having a phenylene skeleton, phenol aralkyl-type epoxy resins having a biphenylene skeleton, naphthol aralkyl-type epoxy resins having a phenylene skeleton, and naphthol aralkyl-type epoxy resin having a biphenylene skeleton; naphthol-type epoxy resins, such as dihydroxy naphthalene-type resins, and epoxy resins obtained by glycidyl-etherifying dimers of hydroxynaphthalene and/or dihydroxy naphthalene; triazine nucleus-containing epoxy resins, such as triglycidyl isocyanurate and monoaryl diglycidyl isocyanurate; bridged cyclic hydrocarbon compound-modified phenol-type epoxy resins, such as dicycloheptadiene-modified phenol-type epoxy resins; sulfur atom-containing epoxy resins, such as bisphenol S-type epoxy resins, and the like. The epoxy resin may be used singly, or jointly used in combination of two or more kinds. When the filling properties in a semiconductor apparatus having a narrow path are taken into account, it is important to decrease the viscosity of the resin composition, and biphenyl-type epoxy resins, bisphenol F-type epoxy resins, bisphenol A-type epoxy resins, phenol aralkyl-type epoxy resins having a phenylene skeleton, and phenol aralkyl-type epoxy resins having a biphenylene skeleton are preferred.

The blending ratio of the total epoxy resin (A) that is used in the resin composition for encapsulating a semiconductor of the invention is not particularly limited, but is preferably equal to or more than 1% by mass and equal to or less than 30% by mass, and more preferably equal to or more than 2% by mass and equal to or less than 25% by mass in the total resin composition for encapsulating a semiconductor. When the blending ratio of the total epoxy resin (A) is equal to or more than the lower limit value, there is little possibility of degradation of flow characteristics and the like.

The resin composition for encapsulating a semiconductor of the invention includes the phenol resin-based curing agent (B). The phenol resin-based curing agent (B) that is used in the resin composition for encapsulating a semiconductor of the invention comprehensively includes monomers, oligomers, and polymers having two or more phenolic hydroxyl groups in one molecule, and the molecular weight and the molecular structure are not particularly limited. Examples thereof include novolac-type resins, such as phenol novolac resins, cresol novolac resins, and naphthol novolac resins; multifunctional phenol resins, such as triphenolmethane-type resins, and alkyl-modified triphenolmethane-type resins; modified phenol resins, such as dicycloheptadiene-modified phenol resins and terpene-modified phenol resins; aralkyl-type resins, such as phenol aralkyl resins having a phenylene skeleton, phenol aralkyl resins having a biphenylene skeleton, naphthol aralkyl resins having a phenylene skeleton, and naphthol aralkyl resins having a biphenylene skeleton; bisphenol compounds, such as bisphenol A and bisphenol F; sulfur atom-containing phenol resins, such as bisphenol S; and the like. These may be used singly, or jointly used in combination of two or more kinds. When the filling properties in a semiconductor apparatus having a narrow path are taken into account, it is important to decrease the viscosity of the resin composition, and phenol novolac resins, cresol novolac resins, naphthol novolac resins, phenol aralkyl resins having a phenylene skeleton, and phenol aralkyl resins having a biphenylene skeleton are preferred.

The blending ratio of (B) the phenol resin-based curing agent that is used in the resin composition for encapsulating a semiconductor of the invention is not particularly limited, but is preferably equal to or more than 0.5% by mass and equal to or less than 30% by mass, and more preferably equal to or more than 1% by mass and equal to or less than 20% by mass. When the blending ratio of (B) the phenol resin-based curing agent is equal to or more than the above lower limit, there is little possibility of degradation of flow characteristics and the like.

As the blending ratio between (A) the epoxy resin and (B) the phenol resin-based curing agent which are used in the resin composition for encapsulating a semiconductor of the invention, the ratio (EP/OH) between the number of epoxy groups (EP) in the total epoxy resin and the number of phenolic hydroxyl groups (OH) in the total phenol resin-based curing agent is preferably equal to or more than 0.8 and equal to or less than 1.4. Within this range, it is possible to suppress degradation of the curing properties of the resin composition, degradation of the glass transition temperature of the curing agent, degradation of moisture resistance reliability, and the like.

The resin composition for encapsulating a semiconductor of the invention includes (C) the inorganic filler. As (C) the inorganic filler that is used in the resin composition for encapsulating a semiconductor of the invention, an inorganic filler that is generally used in a resin composition for encapsulating a semiconductor can be used. Examples thereof include fused silica, crystalline silica, talc, alumina, silicon nitride, and the like, and spherical fused silica is most preferably used. (C) The inorganic filler may be used singly, or jointly used in combination of two or more kinds. The maximum particle size of (C) the inorganic filler is not particularly limited; however, when the filling properties in a semiconductor apparatus having a narrow path are taken into account, it is important not to blend large particles having a particle size that exceeds the height of the narrow path, and the proportion of the inorganic filler that is equal to or more than 45 μm is preferably equal to or less than 1% by mass of the total inorganic filler, the proportion of the inorganic filler that is equal to or more than 32 μm is more preferably equal to or less than 1% by mass of the total inorganic filler, and the proportion of the inorganic filler that is equal to or more than 24 μm is particularly preferably equal to or less than 1% by mass of the total inorganic filler.

The content ratio of (C) the inorganic filler that is used in the resin composition for encapsulating a semiconductor of the invention is not particularly limited; but is preferably equal to or more than 50% by mass and equal to or less than 92% by mass, and more preferably equal to or more than 60% by mass and equal to or less than 90% by mass in the total resin composition for encapsulating a semiconductor. When the content ratio of (C) the inorganic filler is equal to or more than the above lower limit, it is possible to suppress degradation of soldering resistance and the like. When the content ratio of (C) the inorganic filler is equal to or less than the above upper limit, it is possible to suppress degradation of flow characteristics and the like. When the filling properties in a semiconductor apparatus having a narrow path are taken into account, it is important to decrease the viscosity of the resin composition, and the content ratio is preferably equal to or more than 50% by mass and equal to or less than 88% by mass. In addition, when the filling properties of the resin composition for encapsulating a semiconductor during MAP molding are taken into account, the content ratio is preferably equal to or more than 60% by mass and equal to or less than 88% by mass.

The resin composition for encapsulating a semiconductor of the invention includes (D) the curing accelerator. As (D) the curing accelerator that is used in the resin composition for encapsulating a semiconductor of the invention, curing accelerators that promote a reaction between epoxy groups in (A) the epoxy resin and hydroxyl groups in (B) the phenol resin-based curing agent may be used, and a curing accelerator that is generally used can be used. Specific examples thereof include phosphorous atom-containing compounds, such as organic phosphines, tetra-substituted phosphonium compounds, phosphobetaine compounds, adducts of a phosphine compound and a quinone compound, and adducts of a phosphine compound and a silane compound; and nitrogen atom-containing compounds, such as 1,8-diazabicyclo(5.4.0)-undecene-7, benzyldimethylamine and 2-methylimidazole. When the filling properties in a semiconductor apparatus having a narrow path are taken into account, it is important to decrease the viscosity of the resin composition, and phosphorous atom-containing compounds, such as tetra-substituted phosphonium compounds, adducts of a phosphine compound and a quinone compound, and adducts of a phosphine compound and a silane compound are preferred. In addition, when the filling properties of the resin composition for encapsulating a semiconductor during MAP molding are taken into account, it is important to prevent gelatification from proceeding too fast, and phosphorous atom-containing compounds, such as tetra-substituted phosphonium compounds, adducts of a phosphine compound and a quinone compound, and adducts of a phosphine compound and a silane compound are preferred.

It is possible to further use a silane coupling agent in the resin composition for encapsulating a semiconductor of the invention. The silane coupling agent that can be used in the resin composition for encapsulating a semiconductor of the invention is not particularly limited, and examples thereof include silane coupling agents having a mercapto group, silane coupling agents having a secondary amino group, silane coupling agents having a primary amino group, silane coupling agents having an epoxy group, silane coupling agents having an alkyl group, silane coupling agents having a ureide group, silane coupling agents having an acryl group, and the like. When the filling properties in a semiconductor apparatus having a narrow path and the filling properties of the resin composition for encapsulating a semiconductor during MAP molding are taken into account, a silane coupling agent having a secondary amino group are preferred.

Examples of the silane coupling agent (E) having a mercapto group include not only γ-mercapto propyl trimethoxysilane and 3-mercapto propyl methyl dimethoxysilane but also silane coupling agents that develop the same functions as the silane coupling agent having a mercapto group that undergoes thermal decomposition, such as bis(3-triethoxysilylpropyl)tetrasulfideandbis(3-triethoxysilyl propyl) disulfide.

Examples of the silane coupling agent (F) having a secondary amino group include N-β(aminoethyl) γ-aminopropyl trimethoxysilane, N-β(aminoethyl) γ-aminopropyl methyldimethoxysilane, N-phenyl γ-aminopropyl triethoxysilane, N-phenyl γ-aminopropyl trimethoxysilane, N-β(aminoethyl) γ-aminopropyl triethoxysilane, N-6-(aminohexyl) 3-aminopropyl trimethoxysilane, N-(3-(trimethoxy silylpropyl)-1,3-benzene dimethane, and the like.

Examples of the silane coupling agent having a primary amino group include γ-aminopropyl triethoxysilane, γ-aminopropyl trimethoxysilane, and the like.

Examples of the silane coupling agent having an epoxy group include γ-glycidoxy propyl triethoxysilane, γ-glycidoxy propyl trimethoxysilane, γ-glycidoxy propyl methyldimethoxysilane, β-(3,4 epoxy cyclohexyl)ethyl trimethoxysilane, and the like.

The silane coupling agent having an alkyl group includes methyl trimethoxysilane, ethyl trimethoxysilane, and the like.

Examples of the silane coupling agent having a ureide group include γ-ureidopropyl triethoxysilane, hexamethyl disilazane, and the like.

The silane coupling agents having an acryl group include 3-methacryloxy propyl methyl dimethoxysilane, 3-methacryloxy propyl trimethoxysilane, 3-methacryloxy propyl methyl diethoxysilane, 3-methacryloxy propyl triethoxysilane, 3-acryloxy propyl trimethoxysilane, and the like.

In addition, the silane coupling agent may be blended with a silane coupling agent that has previously undergone a hydrolysis reaction. The silane coupling agent may be used singly, or jointly used in combination of two or more kinds.

The lower limit value of the blending ratio of the silane coupling agent that can be used in the resin composition for encapsulating a semiconductor of the invention is preferably equal to or more than 0.05% by mass, and more preferably equal to or more than 0.1% by mass in the total resin composition. When the blending ratio is equal to or more than the lower limit value, the adhesion force with a variety of metal-based members increases, and it is possible to obtain an effect of improving the soldering resistance. In addition, the upper limit value of the blending ratio of the silane coupling agent is preferably equal to or less than 1% by mass, and more preferably equal to or less than 0.7% by mass in the total resin composition. When the blending ratio is equal to or less than the upper limit value, it is possible to obtain favorable soldering resistance in a semiconductor apparatus without increasing the water-absorbing properties of the cured resin composition.

In addition to (A) the epoxy resin, (B) the phenol resin-based curing agent, (C) the inorganic filler, (D) the curing accelerator, and the silane coupling agent, a variety of additives, such as a mold release agent, such as a natural wax, such as carnauba wax, a synthetic wax, such as polyethylene wax, a higher fatty acid, such as stearic acid or zinc stearate, a metallic salt thereof, or paraffin; a colorant, such as carbon black, red iron oxide, titanium oxide, phthalocyanine, or perylene black; an ion-trapping agent, such as a hydrotalcite and a hydrous oxide of an element selected from magnesium, aluminum, bismuth, titanium, and zirconium; a low-stress additive, such as silicone oil or rubber; an adhesiveness-supplying agent, such as thiazoline, diazole, triazole, triazine, or pyrimidine; a flame retardant, such as a brominated epoxy resin, antimony trioxide, aluminum hydroxide, magnesium hydroxide, zinc borate, zinc molybdate, or phosphazene; and the like may be further blended appropriately according to necessity with the resin composition for encapsulating a semiconductor of the invention.

In addition, the resin composition for encapsulating a semiconductor of the invention can be used after the degree of dispersion, flow characteristics, and the like are adjusted by, for example, blending the respective components at room temperature using a mixer or the like, or, furthermore, subjecting the mixture to melting, kneading using a kneading device, such as a roll, a kneader, or an extruder, cooling, and crushing, according to necessity.

Next, the method for manufacturing a semiconductor apparatus of the invention will be described. The semiconductor apparatus of the invention is a semiconductor apparatus having an encapsulating material that encapsulates one or more semiconductor elements stacked or mounted in parallel on a lead frame or circuit substrate having a die pad portion. In order to manufacture a semiconductor by encapsulating semiconductor elements using the resin composition for encapsulating a semiconductor of the invention, the resin composition may be curing-molded by a molding method of the related art, such as transfer molding, compression molding, injection molding, or the like. In addition, it is also possible to collectively encapsulating-mold a plurality of semiconductor elements, and then perform a separating process so as to obtain a semiconductor apparatus. A semiconductor apparatus that is obtained by encapsulating-molding semiconductor elements using the resin composition for encapsulating a semiconductor of the invention having a flow length of equal to or more than 50 cm which is obtained by managing the flow characteristics in a predetermined range for a product inspection of the resin composition for encapsulating a semiconductor according to the method for measuring flow characteristics of the invention in which the mold for measuring flow characteristics of the invention is used can be stably obtained without occurrence of poor filling and the like even when the semiconductor apparatus has a narrow path.

A semiconductor element that is encapsulated using the resin composition for encapsulating a semiconductor element of the invention is not particularly limited, and examples thereof include an integrated circuit, a large-scale integrated circuit, a transistor, a thyristor, a diode, a solid imaging element, and the like.

The form of the semiconductor apparatus that is obtained by the method for manufacturing the semiconductor apparatus of the invention is not particularly limited, and examples thereof include a dual in-line package (DIP), a plastic leaded chip carrier (PLCC), a quad flat package (QFP), a small outline package (SOP), a small outline J-lead package (SOJ), a thin small-outline package (TSOP), a thin quad flat package (TQFP), a tape carrier package (TCP), a ball grid array (BGA), a chip size package (CSP), and the like. In addition, the form of the semiconductor apparatus that is obtained by performing the encapsulating molding process using a resin composition for encapsulating a semiconductor and then the separating process includes a MAP-type ball grid array (BGA), a MAP-type chip size package (CSP), a MAP-type quad flat no-lead (QFN), and the like.

The semiconductor apparatus encapsulated by a molding method, such as the transfer molding, is mounted on an electronic device and the like as it is or after being completely cured at a temperature of approximately 80° C. to 200° C. for a time of approximately 10 minutes to 10 hours.

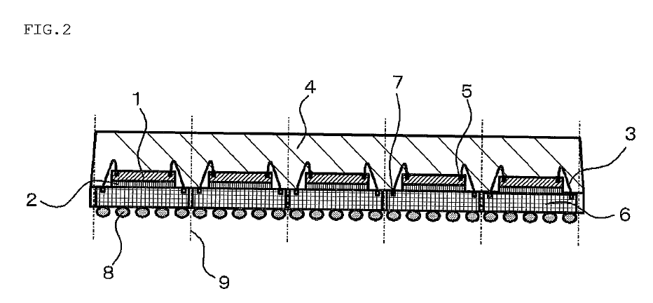

FIG. 2 is an example of a semiconductor apparatus obtained by the method for manufacturing a semiconductor apparatus of the invention, and a cross-sectional view showing the outline after collective encapsulating molding (before separation) in a semiconductor apparatus (MAP-type BGA) in which a plurality of semiconductor elements mounted in parallel on a circuit substrate is collectively encapsulating-molded, and then separated. A plurality of semiconductor elements 1 is fixed in parallel on a circuit substrate 6 through a die bond-cured body 2. An electrode pad 5 of the semiconductor element 1 and an electrode pad 7 of the circuit substrate 6 are electrically joined through bonding wires 3. Soldering balls 8 are formed on a surface of the circuit substrate 6 on the opposite side to the surface on which the semiconductor elements 1 are mounted, and the soldering balls 8 are electrically jointed at the electrode pads 7 of the circuit substrate 6 in the circuit substrate 6. An encapsulating material 4 is, for example, formed of a cured resin composition for encapsulating a semiconductor, and only the single surface of the circuit substrate 6 on which a plurality of the semiconductor elements 1 is mounted is collectively encapsulating-molded with the encapsulating material 4. Further, the semiconductor elements are diced along dicing lines 9 so as to be separated. FIG. 2 shows a semiconductor apparatus after separation, in which one semiconductor element 1 is mounted on the circuit substrate 6, but two or more semiconductor elements may be mounted in parallel or stacked.

### EXAMPLES

Hereinafter, examples of the invention will be shown, but the invention is not limited thereto.

Meanwhile, a mold for evaluating flow characteristics and a resin composition for encapsulating a semiconductor which are used in the examples will be hereinafter shown.

(Mold for Evaluating Flow Characteristics)

A mold for evaluating flow characteristics according to the invention as shown in FIG. 1 (hereinafter also referred to as the “flat flow mold”): a mold for evaluating flow characteristics in which the minimum distance from the cross-sectional center of gravity to the outline in the cross-sectional shape of the flow path is 0.1 mm (the cross-sectional shape of the flow path is a 5 mm-wide and 0.2 mm-high rectangular form), and the flow path has a spiral shape.

Arnold for measuring spiral flow as defined in ANSI/ASTM D 3123-72 (hereinafter also referred to as the “spiral flow mold”): a mold for evaluating flow characteristics in which the minimum distance from the cross-sectional center of gravity to the outline in the cross-sectional shape of the flow path is 0.7 mm (the cross-sectional shape of the flow path is a semicircular form having R1.6 mm (R0.63 inches), and the flow path has a spiral shape.

(Resin Composition for Encapsulating a Semiconductor)

The respective components as shown below were blended at the blending ratios as shown in Table 1, mixed using a mixer, kneaded at 95° C. for 8 minutes using heat rolls, furthermore, cooled, and then crushed so as to obtain a resin composition for encapsulating a semiconductor.

(Epoxy Resin)

Epoxy resin 1: phenol aralkyl-type epoxy resin having a biphenylene skeleton represented by the following formula (1) (manufactured by Nippon Kayaku Co., Ltd., product name: NC3000P, softening point: 58° C., epoxy equivalent: 273)

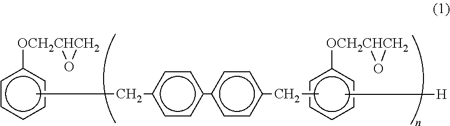

Epoxy resin 2: biphenyl-type epoxy resin having a compound represented by the following formula (2) as a main component (manufactured by Japan Epoxy Resins Co., Ltd., product name: YX-4000, epoxy equivalent: 190, melting point: 105° C.)

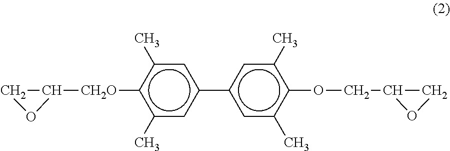

(Phenol Resin-Based Curing Agent)

Phenol resin-based curing agent 1: phenol aralkyl resin having a biphenylene skeleton represented by the following formula (3) (manufactured by Meiwa Plastic Industries, Ltd., product name: MEH-7851SS, softening point: 107° C., hydroxyl group equivalent: 204)

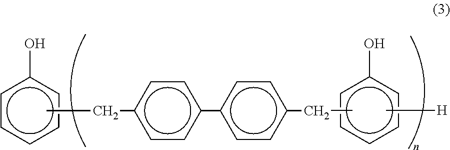

Phenol resin-based curing agent 2: phenol aralkyl resin represented by the following formula (4) (manufactured by Mitsui Chemicals, Inc., product name: XLC-LL, hydroxyl group equivalent: 165, softening point: 79° C.)

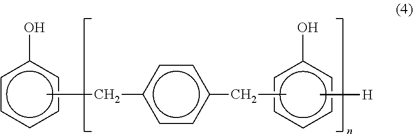

(Inorganic Filler)

Spherical fused silica 1 (average diameter: 6 μm, coarsen powder of equal to or more than 24 μm removed using a sieve)

(Curing Accelerator)

Curing accelerator 1: triphenyl phosphine

Curing accelerator 2: curing accelerator represented by the following formula (5)

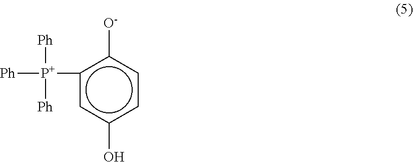

Curing accelerator 3: curing accelerator represented by the following formula (6)

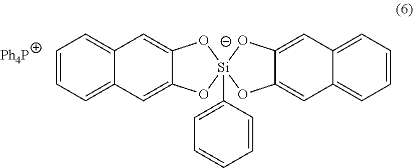

(Coupling Agent)

Silane coupling agent 1: N-phenyl-γ-aminopropyl trimethoxy silane (manufactured by Shin-Etsu Chemical Co., Ltd., product name: KBM-573)

(Other Additives)

Carnauba wax (manufactured by Nikko Fine Product Co., product name: Nikko Carnauba)

Carbon black: (manufactured by Mitsubishi Chemical Corporation, product name: MA-600)

The obtained resin compositions for encapsulating a semiconductor were evaluated by the following method, and the results are shown in Table 1.

Evaluation Method

Flat flow: the resin composition for encapsulating a semiconductor was injected into the mold for evaluating flow characteristics (the flat flow mold) using a low-pressure transfer molder (manufactured by Kohtaki Corporation, KTS-15) under conditions of a mold temperature of 175° C., an injection pressure of 6.9 MPa, and a pressurization time of 120 seconds, and the flow distance from the start point to end point of the flow of the resin composition for encapsulating a semiconductor was obtained as a flow length. The units were cm.

Spiral flow: the resin composition for encapsulating a semiconductor was injected into the mold for measuring spiral flow (the spiral flow mold) using a low-pressure transfer molder (manufactured by Kohtaki Corporation, KTS-15) under conditions of a mold temperature of 175° C., an injection pressure of 6.9 MPa, and a pressurization time of 120 seconds, and the flow distance from the start point to end point of the flow of the resin composition for encapsulating a semiconductor was obtained as a flow length. The units were cm.

Gel time: the resin composition was mixed on a hot plate at 175° C., and a time necessary for the resin composition to be cured was measured. The units were seconds.

Narrow path filling properties: after an article having 36 flip chips (chip size: 10 mm×10 mm×180 μm-thick) having a soldering bump height of 35 μm (3 chips (vertical)×3 chips (horizontal)×4 panels) mounted on a MAP substrate (substrate size: 60 mm×250 mm×230 μm-thick) was installed at the bottom mold of a mold having as many substantially oblong cavities (width 50 mm×depth 50 mm×height 350 μm) as in 4 panels in the top mold, the flip chips mounted on the MAP substrate were collectively encapsulating-molded with the resin composition for encapsulating a semiconductor using a low-pressure transfer molder (manufactured by TOWA Corporation) under conditions of a mold temperature of 175° C., an injection pressure of 9.8 MPa, and a curing time of 120 seconds, and then separated so as to obtain a semiconductor apparatus (the package size was 15 mm×15 mm, and the thickness at the resin-encapsulated portion was 350 μm). At this time, the thinnest portion of the flow path for the resin composition for encapsulating a semiconductor was a bump portion between the substrate and the chip, and the cross-sectional shape thereof was 10 mm wide and 0.035 mm high. With respect to 36 semiconductor apparatuses obtained, the filling properties were confirmed using an ultrasonic imaging apparatus (manufactured by Hitachi Construction Machinery Co., Ltd., FineSAT). A case in which all semiconductor apparatuses were fully filled was determined to be 0, and a case in which even a single semiconductor failed to be filled was determined to be X.

TABLE 1

| | | Test examples | | | | | | | | | | | | |
|---|---|---|---|---|---|---|---|---|---|---|---|---|---|---|
| | | 1 | 2 | 3 | 4 | 5 | 6 | 7 | 8 | 9 | 10 | 11 | 12 | 13 |
| Component (A) | Epoxy resin 1 | 121 | 131 | 120 | 121 | 120 | 128 | 126 | | 119 | 120 | 126 | 137 | |
| | Epoxy resin 2 | | | | | | | | 91 | | | | | 91 |
| Component (B) | Phenol resin-based | 90 | 98 | 90 | 90 | 90 | 81 | 79 | | 89 | 89 | 93 | 101 | |
| | curing agent 1 | | | | | | | | | | | | | |
| | Phenol resin-based | | | | | | | | 79 | | | | | 79 |
| | curing agent 2 | | | | | | | | | | | | | |
| Component (C) | Spherical fused silica 1 | 780 | 760 | 780 | 780 | 780 | 780 | 780 | 820 | 780 | 780 | 770 | 750 | 820 |
| Curing accelerator | Curing accelerator 1 | 2 | 4 | | | 3 | | | 3 | 5 | 4 | | 5 | 4 |
| | Curing accelerator 2 | | | 3 | 2 | | | | | | | 4 | | |
| | Curing accelerator 3 | | | | | | 4 | 8 | | | | | | |
| Coupling agent | Silane coupling agent 1 | 2 | 2 | 2 | 2 | 2 | 2 | 2 | 2 | 2 | 2 | 2 | 2 | 2 |
| Other additives | Carnauba wax | 2 | 2 | 2 | 2 | 2 | 2 | 2 | 2 | 2 | 2 | 2 | 2 | 2 |
| | Carbon black | 3 | 3 | 3 | 3 | 3 | 3 | 3 | 3 | 3 | 3 | 3 | 3 | 3 |
| Characteristics | Flat flow [cm] | 78 | 92 | 60 | 71 | 54 | 108 | 68 | 50 | 30 | 41 | 45 | 47 | 34 |
| | Spiral flow [cm] | 257 | >260 | 192 | 228 | 162 | >260 | 201 | 152 | 98 | 139 | 201 | >260 | 177 |
| | Gel time [seconds] | 62 | 69 | 64 | 47 | 37 | 73 | 66 | 53 | 32 | 54 | 38 | 33 | 41 |
| | Narrow path filling | ◯ | ◯ | ◯ | ◯ | ◯ | ◯ | ◯ | ◯ | X | X | X | X | X |
| | properties | | | | | | | | | | | | | |

1. A mold for measuring flow characteristics which is used to measure the flow characteristics of a resin composition, which is a measurement subject, by injecting the resin composition into a flow path provided in the mold,
wherein the minimum distance from the cross-sectional center of gravity to the outline in the cross-sectional shape of the flow path is equal to or more than 0.02 mm and equal to or less than 0.4 mm.

2. The mold for measuring flow characteristics according to claim 1,
wherein the flow path is a spiral-shaped flow path.

3. The mold for measuring flow characteristics according to claim 1,
wherein the cross-sectional shape of the flow path is a rectangular form, a trapezoidal form, or a semicylindrical form.

4. The mold for measuring flow characteristics according to claim 1,
wherein the maximum width (w) and the maximum height (h) in the cross-sectional shape of the flow path have a relationship of w≦h.

5. The mold for measuring flow characteristics according to claim 4,
wherein the maximum height of the cross-sectional shape of the flow path is equal to or more than 0.05 mm and equal to or less than 0.8 mm.

6. The mold for measuring flow characteristics according to claim 4,
wherein the maximum width of the cross-sectional shape of the flow path is equal to or more than 0.5 mm and equal to or less than 10 mm.

7. A method for measuring flow characteristics comprising:
a process in which a resin composition, which is a measurement subject, is injected into the flow path of the mold for measuring flow characteristics according to claim 1, and made to flow in a single direction; and
a process in which a flow distance from a start point to an end point of the flow of the resin composition is obtained as a flow length.

8. The method for measuring flow characteristics according to claim 7,
wherein the process in which the flow distance is obtained as the flow length is carried out using a low-pressure transfer molder under conditions of a mold temperature of 140° C. to 190° C., an injection pressure of 6.9 MPa, and a pressurization time of 60 seconds to 180 seconds.

9. A method for inspecting a resin composition for encapsulating a semiconductor, comprising:
evaluating the flow characteristics of a resin composition by the method for measuring flow characteristics according to claim 7,
wherein the resin composition is a resin composition for encapsulating a semiconductor, and
a process in which the flow length of the resin composition for encapsulating a semiconductor is measured for a product inspection of the resin composition for encapsulating a semiconductor, the value is compared with a previously specified product standard, and whether a pass or a fail is determined is included.

10. A resin composition for encapsulating a semiconductor which includes (A) an epoxy resin, (B) a phenol resin-based curing agent, (C) an inorganic filler, and (D) a curing accelerator,
wherein the flow length measured by injecting the resin composition for encapsulating a semiconductor into the flow path in the mold for measuring flow characteristics according to claim 1 having a spiral-shaped flow path, the cross-sectional shape of which is substantially a 5 mm-wide and 0.2 mm-high rectangular form, using a low-pressure transfer molder according to the method for measuring flow characteristics according to claim 7 under conditions of a mold temperature of 175° C., an injection pressure of 6.9 MPa, and a pressurization time of 120 seconds is equal to or more than 50 cm, is provided.

11. The resin composition for encapsulating a semiconductor according to claim 10,
wherein, when L₁ indicates the flow length measured by injecting the resin composition for encapsulating a semiconductor into the flow path in the mold for measuring flow characteristics according to claim 1 having a spiral-shaped flow path, the cross-sectional shape of which is substantially a 5 mm-wide and 0.2 mm-high rectangular form, using a low-pressure transfer molder according to the method for measuring flow characteristics according to claim 7 under conditions of a mold temperature of 175° C., an injection pressure of 6.9 MPa, and a pressurization time of 120 seconds, and L₂ indicates the flow length measured by injecting the resin composition for encapsulating a semiconductor into a flow path in a mold for measuring spiral flow, which is defined in ANSI/ASTM D 3123-72, having a spiral-shaped flow path, and the cross-sectional shape of which is a semicircular shape having a radius of R1.6 mm, using a low-pressure transfer molder under conditions of a mold temperature of 175° C., an injection pressure of 6.9 MPa, and a pressurization time of 120 seconds, the following formula:
0.25L₂≦L₁
is satisfied.

12. The resin composition for encapsulating a semiconductor according to claim 10,
wherein the flow length is equal to or more than 60 cm when measured by injecting the resin composition for encapsulating a semiconductor into the flow path in the mold for measuring flow characteristics according to claim 1 which has a spiral-shaped flow path, the cross-sectional shape of which is substantially a 5 mm-wide and 0.2 mm-high rectangular form, using a low-pressure transfer molder according to the method for measuring flow characteristics according to claim 7 under conditions of a mold temperature of 175° C., an injection pressure of 6.9 MPa, and a pressurization time of 120 seconds.

13. The resin composition for encapsulating a semiconductor according to claim 10,
wherein the flow length is equal to or more than 80 cm when measured by injecting the resin composition for encapsulating a semiconductor into the flow path in the mold for measuring flow characteristics according to claim 1 which has a spiral-shaped flow path, the cross-sectional shape of which has substantially a 5 mm-wide and 0.2 mm-high rectangular form, using a low-pressure transfer molder according to the method for measuring flow characteristics according to claim 7 under conditions of a mold temperature of 175° C., an injection pressure of 6.9 MPa, and a pressurization time of 120 seconds.

14. A method for manufacturing a semiconductor apparatus comprising:
encapsulating and molding one or more semiconductor elements stacked or mounted in parallel on a lead frame or a circuit substrate having die pad portion, using the resin composition for encapsulating a semiconductor according to claim 10,
wherein the semiconductor apparatus has a narrow path having the minimum height of equal to or more than 0.01 mm and equal to or less than 0.1 mm.
